(19) United States
(12) Patent Application Publication
(10) Pub. No.: US 2014/0246339 A1
(43) Pub. Date: Sep. 4, 2014

(54) SHOCK-RESISTANT AND/OR WATERPROOF MOBILE DEVICE JACKET

(71) Applicant: MARWARE INC., DBA MARBLUE, HOLLYWOOD, FL (US)

(72) Inventors: CHANSEOL CHUNG, HOLLYWOOD, FL (US); EDWARD MARTIN, HOLLYWOOD, FL (US); PETER SOLOMON, FORT LAUDERDALE, FL (US)

(73) Assignee: MARWARE INC., DBA MARBLUE, HOLLYWOOD, FL (US)

(21) Appl. No.: 14/196,742

(22) Filed: Mar. 4, 2014

Related U.S. Application Data
(60) Provisional application No. 61/772,053, filed on Mar. 4, 2013.

(51) Int. Cl. H05K 5/00

(52) U.S. Cl. CPC H05K 5/0086
USPC 206/37; 29/428

(57) ABSTRACT

A mobile device jacket includes a front lid configured to rest on a front surface of the mobile device, such as a mobile phone and having a circumferential edge, a back cover configured to rest on a back surface of the mobile device and having a circumferential edge, and a rim configured to surround the circumferential edges of the front lid and the back cover resting on the mobile device and seal all parts of the mobile phone in a shock-resistant and waterproof manner. A water-proof material extending from the front lid seals openings of the mobile device when the jacket is assembled and a switch cover of the back cover permit activation of switches or buttons. The front lid may be removed to provide a shock-resistant but non-waterproof jacket.

### CROSS-REFERENCE TO RELATED APPLICATIONS

The present application claims priority to: co-pending Provisional Patent Application No. 61/772,053, filed on Mar. 4, 2013, entitled “SHOCK-RESISTANT OR WATERPROOF MOBILE PHONE JACKET”; that application being incorporated herein, by reference, in its entirety.

### BACKGROUND OF THE INVENTION

1. Field of the Invention

The invention relates to a shock-resistant and/or waterproof mobile device or smart phone jacket or case.

2. Description of the Related Art

Mobile or cell phones and other electronic devices may be easily damaged by shocks and therefore many jackets or cases are available to reduce such risks. In addition, such phones or devices can be completely destroyed by even a momentary emersion into liquid. Many shock- and/or water-resistant cases or jackets are available in different shapes and sizes. The prior art waterproof cases or jackets for smart phones, such as the iPhone®, are either skins or coatings which are relatively permanently affixed to the device or they are very large and cumbersome cases. In both cases, at least some functions of the device are hampered or rendered inactive or the advantage of having a small device is eliminated by the size of the case.

### BRIEF SUMMARY OF THE INVENTION

It is accordingly an object of the invention to provide a shock-resistant or waterproof mobile device jacket, which overcomes the hereinafore-mentioned disadvantages of the heretofore-known jackets of this general type and which is neither cumbersome, nor permanently attached, and can be converted between a shock-resistant jacket and a waterproof jacket.

With the foregoing and other objects in view there is provided, in accordance with one particular embodiment of the invention, a mobile device jacket, comprising a front lid configured to rest on a front surface of the mobile phone or other mobile device and having a circumferential edge, a back cover configured to rest on a back surface of the mobile device and having a circumferential edge, and a rim configured to surround the circumferential edges of the front lid and the back cover resting on the mobile phone and seal all parts of the mobile phone in a shock-resistant and waterproof manner. The front lid is removable to expose at least one of a switch, both top and bottom microphones and speakers, earphone jack port, and full front touch display surface, while leaving the back cover and the rim on the mobile phone in a shock-resistant but non-waterproof manner after assembly. Thus, the jacket is small, easily assembled and removed and convertible between a waterproof and shock-resistant jacket and a merely shock-resistant jacket, while not overly impairing the functions of the device.

In accordance with another embodiment of the invention, the rim has sections configured to be aligned with edges of the mobile phone, hinges between the sections and a latch squeezing the sections against the edges of the mobile phone when latched. The hinges, which in one particular embodiment are living hinges, make the rim easily assembled and disassembled.

In accordance with a further embodiment of the invention, the front lid has a transparent front surface and at least one water-proof extension substantially perpendicular to the transparent front surface at the circumferential edge of the front lid, the back cover has a back surface and a wall substantially perpendicular to the back surface and surrounding the circumferential edge of the back cover, and the at least one water-proof extension is disposed between the wall and the mobile device and seal at least one switch, microphone, speaker, port or opening of the mobile device when the front lid, the back cover and the rim are assembled on the mobile device. In another particular embodiment of the invention, at least two extensions are used. The at least one extension, which may be attached to the back cover instead of the front lid or may be a completely separate part, is at least partly formed of rubbery material in one particular embodiment and is key to making the jacket waterproof, since the extension(s) seal all remaining openings of the mobile phone not sealed by the rear cover, while allowing sound to be transmitted therethrough.

In accordance with another embodiment of the invention, the front lid has a transparent front surface with a rubbery seal or flexible film covering and allowing activation of a home button of the mobile device or phone. Thus, the home button is made waterproof, but can be activated.

In accordance with an additional embodiment of the invention, the back cover has knobs and/or a switch cover covering and allowing activation of volume buttons of the mobile device or phone. Similarly, the back cover has a knob or switch cover covering and allowing activation of a power button and/or mute button of the mobile device or phone.

In accordance with a further embodiment of the invention, the back cover has openings in alignment with at least one switch, microphone, speaker, port or opening of the mobile phone. The openings require the transmission of sound to pass only through the rubbery extension(s) and thus not be overly hindered.

Other features which are considered as characteristic for the invention are set forth in the appended claims.

Although the invention is illustrated and described herein as embodied in a shock-resistant or waterproof mobile device jacket, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIGS. 1-6 are respective diagrammatic front-elevational, top-plan, bottom-plan, left side-elevational, right side-elevational and rear-elevational views of an assembled waterproof mobile device jacket according to the invention;

FIG. 7 is an enlarged, perspective view of the waterproof mobile device jacket in the assembled state;

FIG. 8 is a perspective view of the waterproof mobile device jacket with a rim in a partly disassembled state;

FIG. 9 is a perspective view of the waterproof mobile device jacket with the rim in a fully disassembled state;

FIG. 10 is an exploded perspective view of the waterproof mobile device jacket;

FIGS. 11-15 are respective front-elevational, top-plan, bottom-plan, left side-elevational and right side-elevational views of an assembled shock-resistant mobile device jacket according to the invention;

FIG. 16 is an enlarged, perspective view of the shock-resistant mobile device jacket in an assembled state;

FIG. 17 is a perspective view of the shock-resistant mobile device jacket with a rim in a partly disassembled state; and

FIG. 18 is an exploded perspective view of the shock-resistant mobile device jacket.

FIG. 19 is an exploded perspective view of a waterproof mobile device jacket in accordance with a further embodiment of the invention.

### DETAILED DESCRIPTION OF THE INVENTION

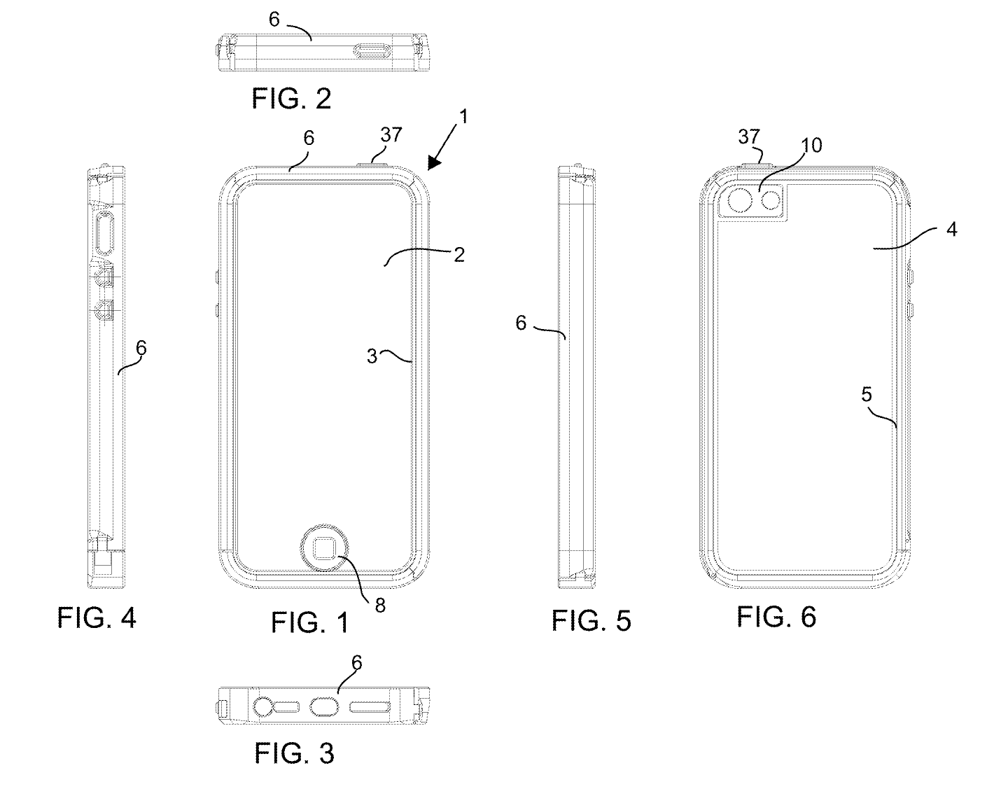

Referring now to the figures of the drawing in detail and first, particularly, to FIGS. 1-6 thereof, there is seen a waterproof mobile device jacket 1 disposed on a mobile phone. The jacket 1 is disposed on an iPhone® in the illustrated embodiment, but the jacket may be used to protect any mobile device or phone and it is only the dimensions and locations of accommodations of the jacket for openings and buttons, etc. which would need to change.

The jacket 1 includes three primary components, namely a front lid 2, a back cover 4 and a rim 6. The front lid 2 is formed of a transparent and flexible plastic, allowing a user to access the touch screen of the mobile phone. The front lid 2 also has a button cover 8 covering the so-called home button of the phone. In one particular embodiment of the invention, the button cover 8 is made from a flexible film that allows for a fingerprint sensor incorporated into the underlying button of the device to read your fingerprints, as well as to allow the user to press or actuate the underlying button. Alternately, a flexible, rubbery seal may be used as the button cover 8, as desired. The button cover 8 may be depressed to activate the home button, or any other button underlying the button cover 8. The back cover 4 may be formed of an over-mold with soft plastic such as TPE, TPU, or any other synthetic rubber or soft resin and may or may not be transparent or carry any sort of decoration. The back cover 4 has a window 10 covering a camera lens and a flash, when used on an iPhone or other device having a rear-facing camera and/or flash. In the present particular embodiment, the rim 6 is formed of POM resin, but may also be made from other materials including, but not limited to, a metal, such as aluminum.

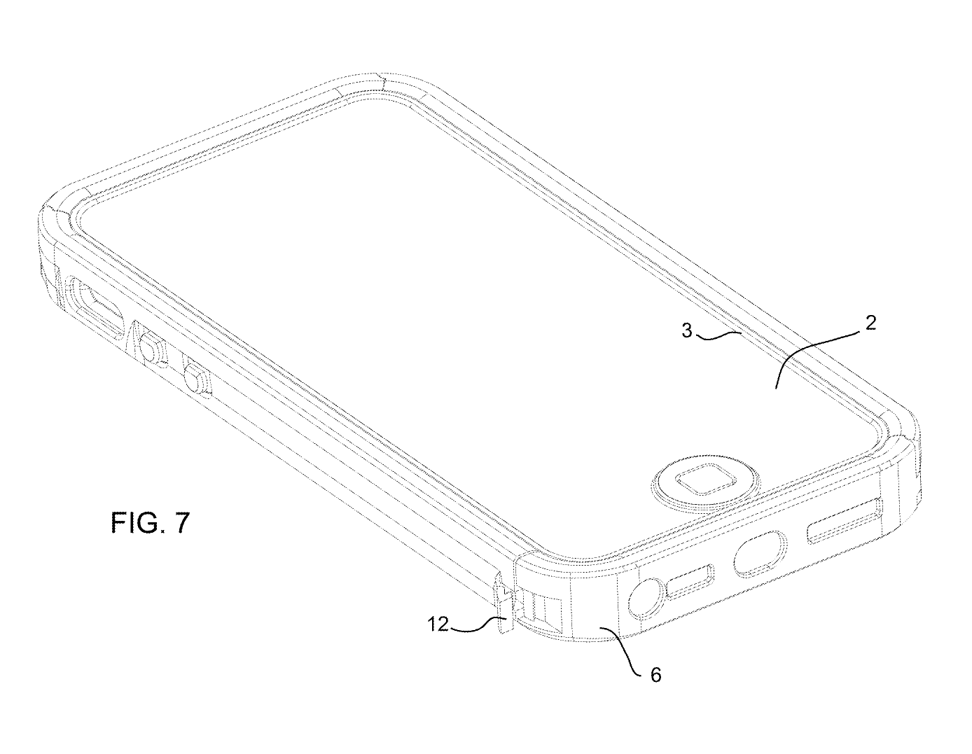

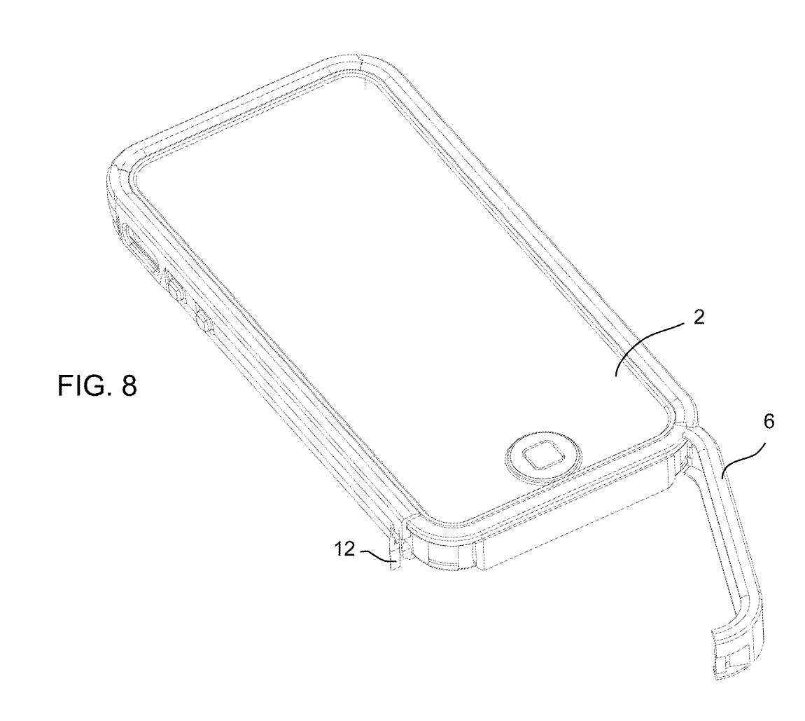

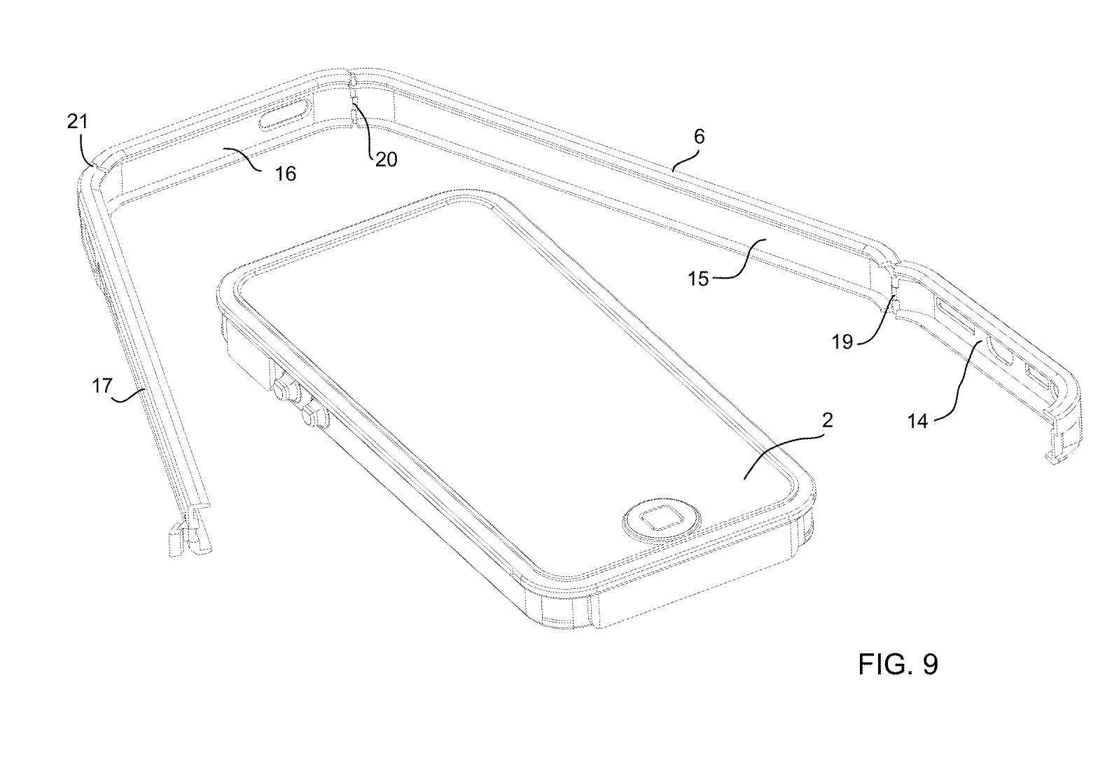

It can be seen from FIG. 7 that a latch 12 is provided for squeezing and holding the rim 6 in place. Latch 12 can be opened for removal of the rim 6. Referring to FIGS. 1, 6 and 7, it is seen that when in the assembled state, bezels 3, 5 on the rim 6 respectively overlap circumferential edges of the front lid 2 and the back cover 4 to tightly hold them in place. FIG. 8 illustrates a state of the mobile device jacket 1 wherein the latch 12 is open and the rim 6 has been partly removed, whereas in FIG. 9 the rim 6 has been completely removed by rotating sections 14-17 of the rim 6 at hinges 19-21.

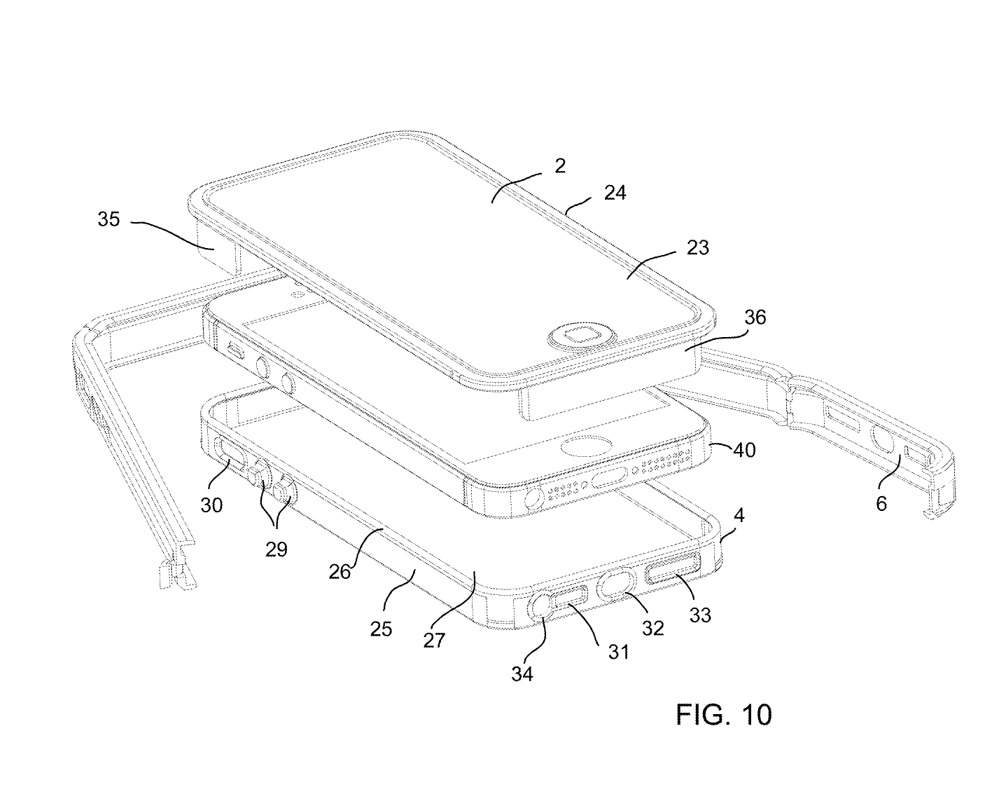

The exploded view of FIG. 10 shows the rim 6 configured to surround the respective circumferential edges 24, 26 of the front lid 2 and the back cover 4, respectively, to waterproof a mobile device 40, such as a mobile phone. FIG. 10 also shows that the front lid 2 of the present embodiment has two extensions 35, 36 extending perpendicularly to a transparent surface 23. The extensions 35, 36 are preferably formed of rubbery material, such as rubber, TPE, TPU, any other synthetic rubber or soft resin, or silicone. In the most preferred embodiment, the extensions 35, 36 are flexible, water-proof and transmissive to sound. The back cover 4 has a wall 25 completely encircling or surrounding a surface 27 forming a tray or trough for receiving the mobile device 40. In one particular embodiment of the invention, the wall 25 of the rear cover 4 is the same height of the side edges of the device 40.

When in the assembled state, the extensions 35, 36 extend outside the mobile device 40 and inside the wall 25, with the rim 6, which overlays and circumscribes the wall 25, squeezing and locking the front lid 2 to the back cover 4 with the mobile device 40 therebetween. The extensions 35, 36 somewhat muffle the sound entering the microphone or leaving the speaker(s) of the mobile phone and block access to ports, docks and jacks.

Finally, as also illustrated in FIG. 10, the wall 25 of the rear cover 4 has knobs and/or switch covers 29 which are in alignment with volume control buttons on the mobile device 40 and openings 30-34 corresponding to at least one mute switch, microphone, speaker, charging dock or earphone or earbud port or opening of the mobile device 40. The rim 6 is tightly squeezed on and presses and seals the rubbery extensions 35, 36 against the openings 30, 31, 32, 33 and 34 when the latch 12 is closed, preventing water from entering any part of the jacket 1 and reaching the mobile device 40. For that reason, the extensions 35, 36 are only long enough to cover the openings 30-34 in the particular mobile device 40, but not the switch covers 29 or a switch cover 37 shown in FIGS. 1 and 6 which also protrudes from the back cover 4 in alignment with a power button of the mobile device 40. Of course, if desired, the extensions 35, 36 could be disposed on the back cover 4 instead of the front lid 2 or the extensions 35, 36 could be completely separate pieces put in place when the jacket is assembled. Once assembled, the mobile device jacket 1 is both shock-proof and water-proof, wherein the extensions 35, 36 of the top lid 2 prevent liquid from entering openings 30-34 in the rim 6 and rear cover 4.

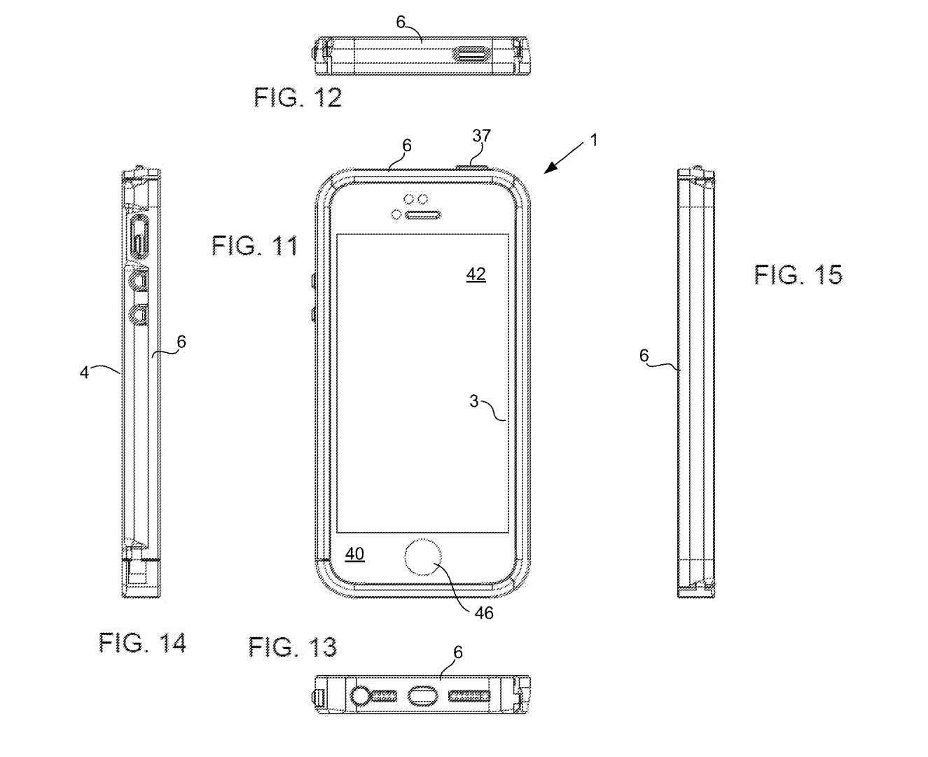

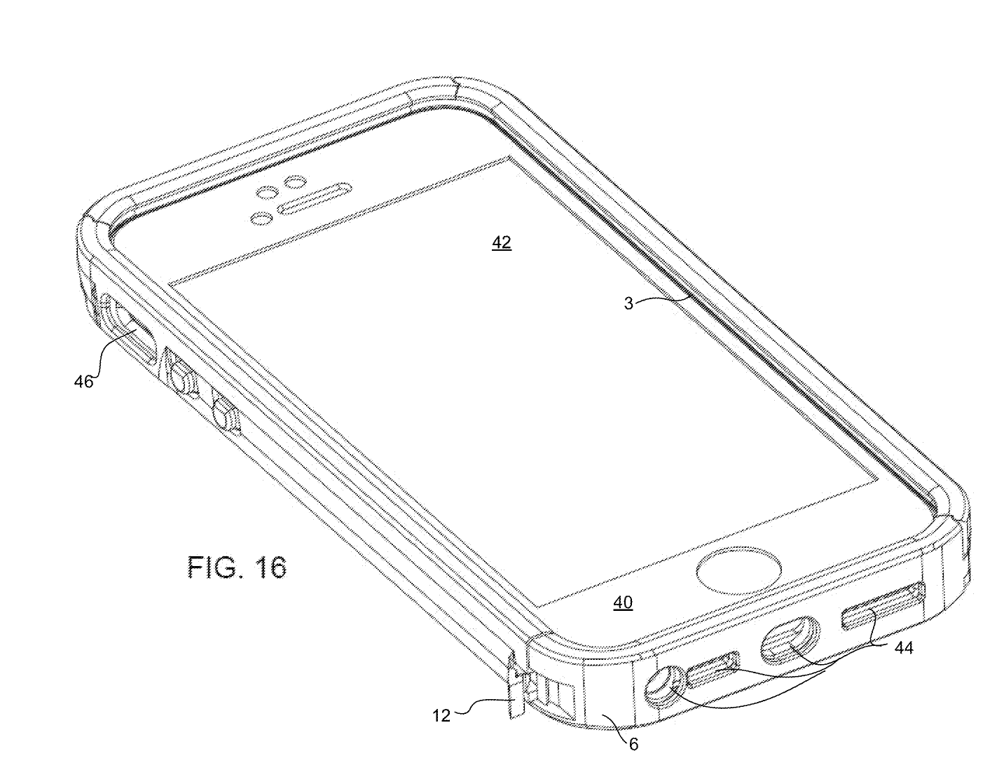

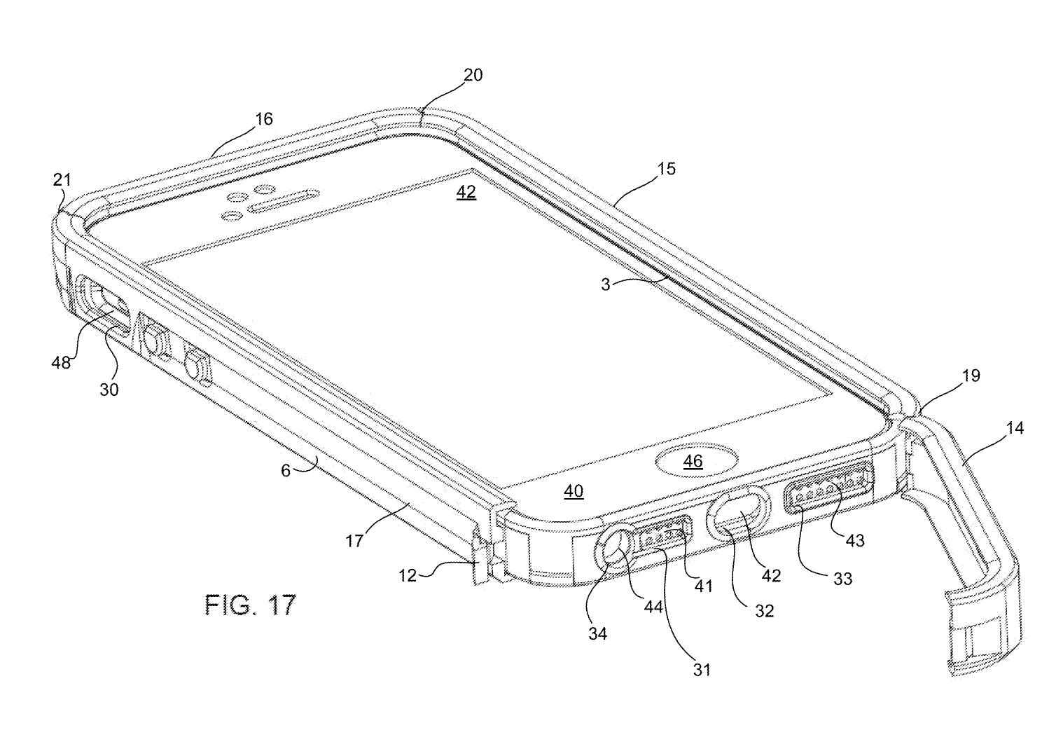

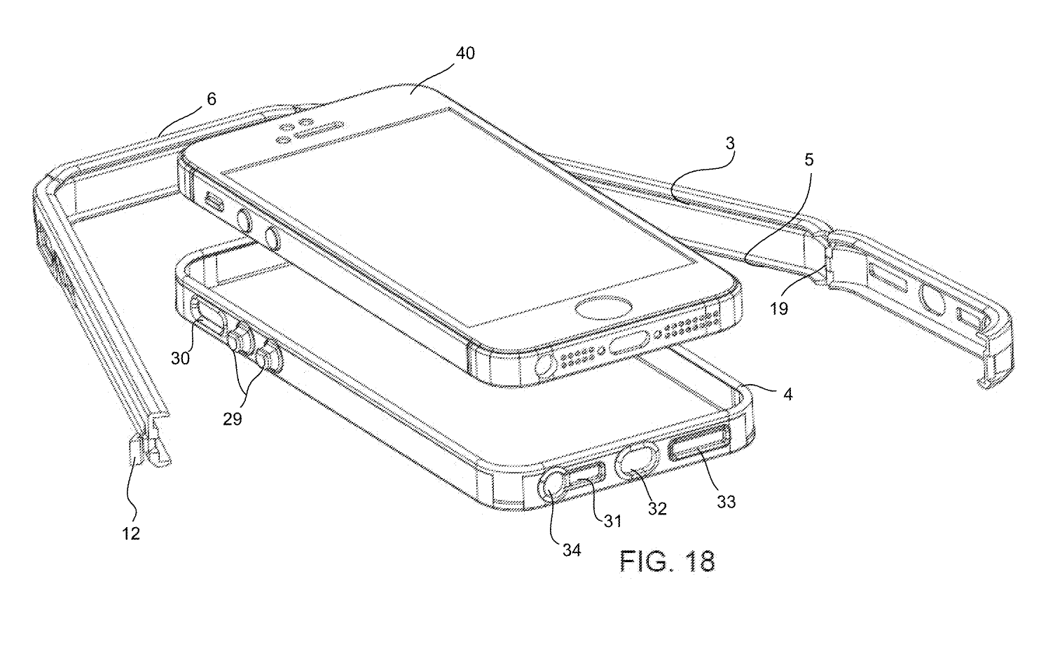

Referring now to FIGS. 11-18, wherein like reference numbers represent the same elements, there is shown a second embodiment of the present invention. In the embodiment of FIGS. 11-18, there is shown a mobile device jacket that is shock-proof, but not waterproof, and which is formed using a subset of the components used to compose the mobile device jacket 1 of FIGS. 1-10. More particularly, in one particular preferred embodiment of the invention, the jacket 1 of FIGS. 1-10 can be reconfigured for use without the front lid 2. In such a configuration, the jacket provides shock protection to the electronic device 40, but is not waterproof and any buttons (other than the volume control buttons covered by knobs 29 of the rear cover 4), switches, microphones, speakers and ports or openings of the mobile phone 40 will not be covered or sealed. As can be seen more particularly in FIG. 17, the mobile device 40 is first placed into the rear cover 4 and then the rim 6 is wrapped-around the periphery(i.e., around the peripheral sidewall 25) of the rear cover 4 and locked into place using the latch 12. In this configuration, the bezel 3 of the rim 6 will engage the front face of the mobile device 40 at or near a periphery of the touch sensitive screen 42. The other bezel 5 will engage with the rear cover 4 as described in connection with the first embodiment of FIGS. 1-10.

Without the front lid, there is no longer any muffling of the sound entering the microphone or leaving the speaker(s) of the mobile phone or blockage of access to ports, docks and jacks. For example, without the extensions 35, 36, switch 48 of the mobile device 40 is accessible through the opening 30 in the rear cover 4. Similarly, the input jacks 42, 44 of the mobile device 40 are accessible through the openings 32, 34 in the rear cover 4. Additionally, sound can pass freely to and from the microphone jack and speakers 41, 43 via the openings 31, 33 in the rear cover 4, unhindered by the extensions 35, 36. As a further benefit, the removal of the front lid 2 additionally improves the sensitivity of, and accessibility to, the touch screen 42 and home button 46 of the mobile device 40.

Of course, the jacket of the first embodiment may be converted to the jacket of the second embodiment by merely removing the front lid 2 and vice versa. In one particular embodiment of the invention, all three primary elements (front lid 2, rear cover 4 and rim 6) are provided as a kit to the user, and the user can decide whether or not to use all three components, or a subset thereof. In another particular embodiment, the rear cover 4 and rim 6 are sold as a kit to the user, for use in assembling a shock-proof, but not water-proof case. In such an embodiment, the front lid 2 can be offered as a separately purchasable add-on component for water-proofing the case, if desired.

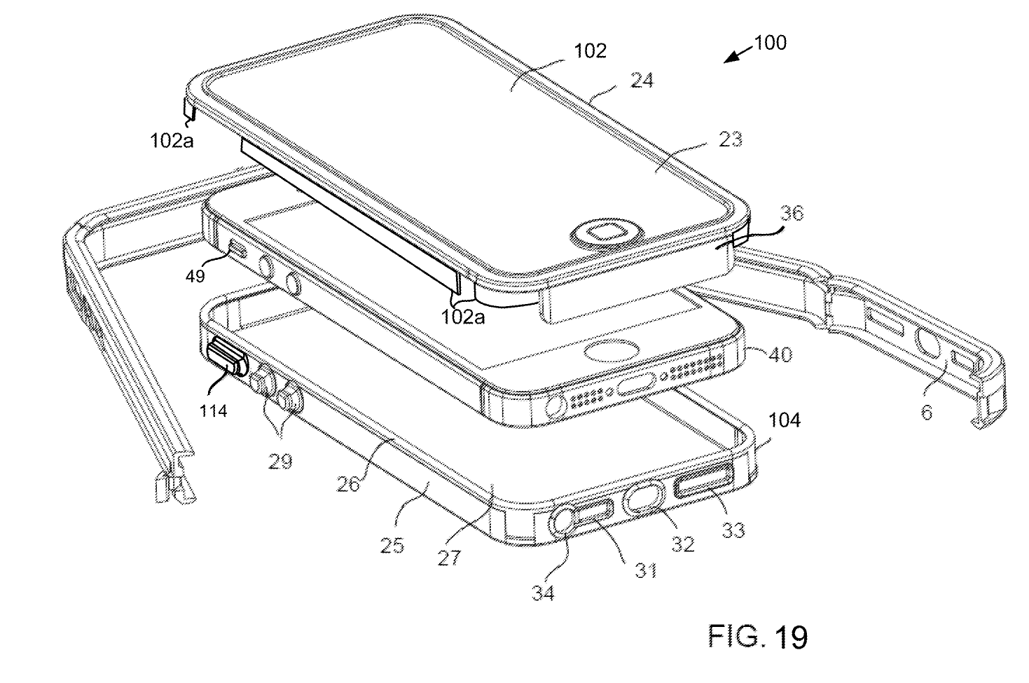

Referring now to FIG. 19, there is shown a further embodiment of a waterproof mobile device jacket 100, in accordance with one particular embodiment of the present invention. As with the jacket 1 of FIGS. 1-10, the jacket 100 includes three primary portions: a front lid 102, a rear cover 104 and a rim 6. In the present embodiment, the front lid 102 and rear cover 104 are substantially the same as described in connection with the front lid 2 and rear cover 4 in FIGS. 1-16, with like reference numbers refer to the same elements throughout the drawings. However, in the present embodiment, the extension 35 of FIGS. 1-16 has been omitted from the lid 102 and a further switch cover 114 has been added to the rear cover 104 in order to provide a seal over the silent/mute switch and volume buttons of the mobile device 40.

More particularly, in accordance with the present embodiment of the invention, the rear cover 104 has switch cover 114 that permits activation of the silent switch and volume buttons of the mobile device 40. As with the previous embodiments, the rear cover 104 also has a switch cover 37 that allows activation of a power button of the mobile device 40. However, the present embodiment provides the rear cover 104 with a switch cover 114 (which replaces the extension 35 of FIGS. 1-10), that seals the rear cover over a mute button 49 of the mobile device 40, while permitting actuation of that button. Thus, in the present invention, only one extension (extension 36 of FIGS. 1-10 and 19) is provided. Additionally, if desired, a wall or flange 102a can optionally extend perpendicularly downward from the edge of the front lid 102, to ensure better alignment and/or engagement with the rear cover 104. In contrast to the extension 36, the flange 102a need not be made out of a rubbery or flexible material and does not need to have sound transmissive properties. If desired, such a flange 102a could also be provided in connection with the front lid 2 of FIGS. 1-10.

Additionally, as described above, the extension 36 may extend from the front lid 102 or, if desired, may be a separate piece placed into the rear cover 104 separately from the front lid 102. However, it should be noted that the device jacket 100 of the present embodiment can be used in a shock-proof, water-proof configuration including all three main components 102, 104, 6, or may be used in a shock-proof only configuration, by assembling the rear cover 104 and rim 6 without the front lid 102, as described above in connection with FIGS. 11-16.

Referring now to FIGS. 11-16 and 19, to assemble the shock-proof case, the mobile device 40 is first placed into the rear cover 4, 104, with the back cover of the mobile device 40 against the inner face 27 of the rear cover 4, 104 and the side edges of the device 40 surrounded by the wall 25 of the rear cover 4, 104. The rim 6 is then wrapped around the wall 25, with the top bezel 3 of the rim 6 above the screen 42 of the device 40. The rim 6 is then locked into place by securing the latch 12.

In accordance with one particular embodiment of a method for assembling a shock-proof and waterproof case as shown in FIGS. 1-10 and 19, the front lid 2, 102 is placed over the face of the mobile device 40, with the extensions (35, 36 of FIGS. 1-10 or only 36 of FIG. 19) hanging over the edge(s) of the mobile device 40. The front lid 2, 102 and device 40 are then snapped into the rear cover 4, with the extension(s) 35 and/or 36 disposed inside the wall 25 of the rear cover 4, 104. As discussed herein, if the extensions 35, 36 are separate pieces, they can be fixed into the rear cover 4, 104 before the device 40 is placed into the rear cover 4, 104 and/or before the front lid 2, 102 is placed on the device 40 (which can happen after the device 40 is inserted into the rear cover 4, 104, if desired). Additionally, if using an embodiment wherein the lid 102 has a flange 102a, the flange 102a would additionally be inserted into the rear cover 104, between the device 40 and the wall 25. With the front lid 2, 102 mated with the rear cover 4, 104 with the extension(s) 35 and/or 36 and device 40 entrapped therebetween, the rim 6 is secured around the wall 25 clamping the front lid 2, 102 and rear cover 4, 104 together, with the bezels 3, 5 of the rim 6.

The present invention provides a convenient, easy-to-use, shock-resistant and/or waterproof mobile device or smart phone jacket or case. Accordingly, while a preferred embodiment of the present invention is shown and described herein, it will be understood that the invention may be embodied otherwise than as herein specifically illustrated or described, and that within the embodiments certain changes in the detail and construction, as well as the arrangement of the parts, may be made without departing from the principles of the present invention as defined by the appended claims.

1. A mobile device jacket, comprising:
a front lid configured to rest on a front surface of the mobile device and having a circumferential edge;
a back cover configured to rest on a back surface of the mobile device and having a circumferential edge; and
a rim configured to surround said circumferential edges of said front lid and said back cover resting on the mobile device and seal all parts of the mobile device in a shock-resistant and waterproof manner.

2. The jacket according to claim 1, wherein said rim has sections configured to be aligned with edges of the mobile device, hinges between said sections and a latch squeezing said sections against the edges of the mobile device when latched.

3. The jacket according to claim 1, wherein:
said front lid has a transparent front surface and at least one extension substantially perpendicular to said transparent front surface at said circumferential edge of said front lid;
said back cover has a back surface and a wall substantially perpendicular to said back surface and surrounding said circumferential edge of said back cover; and
said at least one extension disposed between said wall and the mobile device and seal at least one switch, microphone, speaker, port or opening of the mobile device when said front lid, said back cover and said rim are assembled on the mobile device.

4. The jacket according to claim 1, wherein:
said front lid has a transparent front planar surface;
said back cover has a back planar surface and a wall substantially perpendicular to said back planar surface and surrounding said circumferential edge of said back cover; and
at least one extension disposed substantially perpendicular to at least one of said planar surfaces, said at least one extension being located between said wall and the mobile device and sealing at least one switch, microphone, speaker, port or opening of the mobile device when said front lid, said back cover and said rim are assembled on the mobile device.

5. The jacket according to claim 3, wherein said at least one extension is at least partly formed of rubbery material.

6. The jacket according to claim 1, wherein said front lid has a transparent front surface with a flexible portion and allowing activation of a home button of the mobile phone.

7. The jacket according to claim 1, wherein said back cover has knobs covering and allowing activation of volume buttons of the mobile phone.

8. The jacket according to claim 1, wherein said back cover has a knob covering and allowing activation of a power button of the mobile device.

9. The jacket according to claim 1, wherein said back cover has openings in alignment with at least one switch, microphone, speaker, port or opening of the mobile device.

10. The jacket according to claim 1, wherein said front cover is removable to expose at least one switch, microphone, speaker, port or opening of the mobile device while leaving said front lid and said rim on the mobile device in a shock-resistant but non-waterproof manner after assembly.

11. A mobile device jacket, comprising:
a rear cover including a back portion configured to rest on a back surface of the mobile device and having a circumferential edge, and a wall around said circumferential edge, said rear cover additionally including a wall extending perpendicular to said back portion ; and
a rim configured to surround said wall and said circumferential edges of said rear cover resting on the mobile device to cover a portion of the mobile device in a shock-resistant manner.

12. The jacket according to claim 11, wherein said rim has sections configured to be aligned with edges of the mobile device, hinges between said sections and a latch squeezing said sections against said wall when latched.

13. The jacket according to claim 11, further comprising a front lid including a transparent surface and a flexible portion aligned over at least one button on a front face of the mobile device.

14. The jacket according to claim 13, further comprising at least one water-proof extension covering openings in said wall of said rear cover.

15. The jacket according to claim 14, wherein said at least one water-proof extension is fixed to and extends from said front lid.

16. A method of assembling a mobile device case around a mobile device, comprising the steps of:
providing a rear cover including a back portion configured to rest on a back surface of the mobile device and having a circumferential edge, the rear cover additionally including a wall around the circumferential edge, the wall extending perpendicular to said back portion;
placing the mobile device into the rear cover with the back surface of the mobile device resting on the back portion of the rear cover and the wall of the rear cover surrounding a side edge of the mobile device; and
securing a rim around the wall of the rear cover.

17. The method of assembling a mobile device case of claim 16, further including the step of providing a front lid.

18. The method of assembling a mobile device case of claim 17, further comprising the step of placing at least one water-proof extension over holes in the rear cover.

19. The method of assembling a mobile case of claim 18, wherein the assembling step includes placing the at least one water-proof extension outside the edge of the mobile device and inside the wall of the rear cover.

20. The method of assembling a mobile case of claim 19, wherein the front lid includes the at least one water-proof extension secured thereto.
